(19) United States
(12) Patent Application Publication
(10) Pub. No.: US 2024/0337021 A1
(43) Pub. Date: Oct. 10, 2024

(54) SUBSTRATE PROCESSING APPARATUS, PROCESS VESSEL, METHOD OF PROCESSING SUBSTRATE, METHOD OF MANUFACTURING SEMICONDUCTOR DEVICE AND RECORDING MEDIUM

(71) Applicant: KOKUSAI ELECTRIC CORPORATION, Tokyo (JP)

(72) Inventor: Yusaku OKAJIMA, Toyama-shi (JP)

(73) Assignee: KOKUSAI ELECTRONIC CORPORATION, Tokyo (JP)

(21) Appl. No.: 18/746,499

(22) Filed: Jun. 18, 2024

Related U.S. Application Data
(63) Continuation of application No. PCT/JP2021/048598, filed on Dec. 27, 2021.

(51) Int. Cl. C23C 16/455; C23C 16/34; H01L 21/02

(52) U.S. Cl. CPC C23C 16/45587; C23C 16/345; H01L 21/0217

(57) ABSTRACT

There is provided a technique that includes: a vessel capable of housing a substrate; a gas flow path continuous with the vessel; and a first connection through which a constituent wall of the vessel and a constituent wall of the gas flow path are connected, in which an extension line through the first connection of the constituent wall of the vessel and an extension line through the first connection of the constituent wall of the gas flow path each cross an axis extending from a center of the vessel to the gas flow path.

### CROSS-REFERENCE TO RELATED APPLICATION

This application is a Bypass Continuation application of PCT International Application No. PCT/JP2021/048598, filed on Dec. 27, 2021, the entire contents of which are incorporated herein by reference.

### BACKGROUND

### Field

The present disclosure relates to a substrate processing apparatus, a process vessel, a method of processing a substrate, a method of manufacturing a semiconductor device, and a recording medium.

### Description of the Related Art

A substrate processing apparatus including a reaction tube, in which processing gas is supplied horizontally to a substrate in the reaction tube and is exhausted horizontally from the reaction tube has been disclosed.

### SUMMARY

In such an apparatus as described above, at the time of exhaust of processing gas from the reaction tube, hitting of the processing gas against a wall may cause swirling current to occur. Such occurrence of swirling current in the reaction tube may cause the processing gas to stay or a rise in the partial pressure of the processing gas, leading to a deterioration in the in-plane thickness uniformity of a film on a substrate in substrate processing.

The present disclosure provides a technique enabling an improvement in the in-plane thickness uniformity of a film formed on a substrate.

According to an embodiment of the present disclosure,
there is provided a technique that includes:
a vessel capable of housing a substrate;
a gas flow path continuous with the vessel; and
a first connection through which a constituent wall of the vessel and a constituent wall of the gas flow path are connected, in which
an extension line through the first connection of the constituent wall of the vessel and an extension line through the first connection of the constituent wall of the gas flow path each cross an axis extending from a center of the vessel to the gas flow path.

### BRIEF DESCRIPTION OF THE DRAWINGS

FIG. 1 is a schematic longitudinal sectional view of a substrate processing apparatus in an embodiment of the present disclosure.

FIG. 2 is a cross sectional view of a process vessel in the embodiment of the present disclosure.

FIG. 3 illustrates, in detail, a gas supplier in the embodiment of the present disclosure.

FIG. 4 illustrates, in detail, gas supply holes provided to nozzles in FIG. 3.

FIG. 5 illustrates a schematic configuration of a controller in the substrate processing apparatus in the embodiment of the present disclosure and is a block diagram of a control system for the controller.

FIG. 6 illustrates a substrate processing sequence in the embodiment of the present disclosure.

FIG. 7 is a detailed flow chart of a film processing step in FIG. 6.

FIGS. 8A to 8C illustrate exemplary chemical structural formulae of gas in the embodiment of the present disclosure.

FIGS. 9A to 9C are explanatory graphs for gas available in the embodiment of the present disclosure.

FIG. 10A is an explanatory view for a gas flow in a reaction tube in the embodiment of the present disclosure, and FIG. 10B is an explanatory view for a gas flow in a reaction tube in a comparative example.

FIG. 11A is an explanatory view for a gas flow path in the embodiment of the present disclosure, and FIG. 11B is an explanatory view for a modified example of the gas flow path in the embodiment of the present disclosure.

FIG. 12 is a cross sectional view of a modified example of the process vessel in the embodiment of the present disclosure.

### DETAILED DESCRIPTION

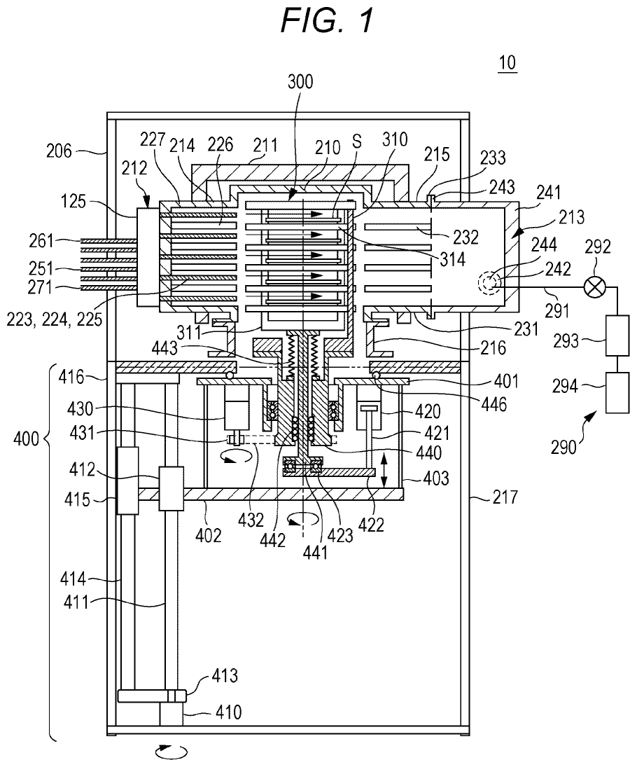

Embodiments of the present disclosure will be described with reference to FIGS. 1 to 12. Note that the drawings used in the following description are all schematic and thus, for example, the dimensional relationship between each constituent element and the ratio between each constituent element illustrated in the drawings do not necessarily coincide with realities. In addition, for example, a plurality of drawings does not necessarily coincide with each other in the dimensional relationship between each constituent element or in the ratio between each constituent element.

### (1) Configuration of Substrate Processing Apparatus

The configuration of a substrate processing apparatus 10 will be described with FIG. 1.

The substrate processing apparatus 10 includes a reaction-tube storage chamber 206. In addition, the substrate processing apparatus 10 includes, in the reaction-tube storage chamber 206, a reaction tube 210 that is a cylindrical vessel extending vertically, a heater 211 serving as a heat generator (furnace body) disposed along the outer circumference of the reaction tube 210, a gas supply structure 212, and a gas exhaust structure 213. The gas supply structure 212 may include an upstream gas guide 214 and nozzles 223, 224, and 225 described later. The gas exhaust structure 213 may include a downstream gas guide 215 described later. The reaction tube 210 is capable of housing substrates S.

The gas supply structure 212 is provided upstream in the direction of a gas flow of the reaction tube 210. Gas is supplied from the gas supply structure 212 into the reaction tube 210 such that the gas is supplied horizontally to the substrates S. The gas exhaust structure 213 is provided downstream in the direction of a gas flow of the reaction tube 210. The gas in the reaction tube 210 is discharged through the gas exhaust structure 213. The gas supply structure 212, the reaction tube 210, and the gas exhaust structure 213 are in horizontal communication.

On the upstream side of the reaction tube 210 between the reaction tube 210 and the gas supply structure 212, provided is the upstream gas guide 214 that guides the flow of the gas supplied from the gas supply structure 212. On the downstream side of the reaction tube 210 between the reaction tube 210 and the gas exhaust structure 213, provided is the downstream gas guide 215 that guides the flow of the gas discharged from the reaction tube 210. The reaction tube 210 has a lower end supported by a manifold 216.

The reaction tube 210, the upstream gas guide 214, and the downstream gas guide 215 are provided as a continuous structure, and are formed of a material, such as quartz or SiC. The reaction tube 210, the upstream gas guide 214, and the downstream gas guide 215 are achieved with a heat transfer member that transfers heat radiated from the heater 211. The heat from the heater 211 causes rises in the temperatures of the substrates S and the gas.

The gas supply structure 212 is in connection with a gas supply pipe 251, a gas supply pipe 261, and a gas supply pipe 271, and includes a distributor 125 that distributes the gas supplied from each gas supply pipe. A nozzle 223, a nozzle 224, and a nozzle 225 are provided on the downstream side of the distributor 125. The nozzles 223, 224, and 225 are connected, respectively, to the downstream sides of the gas supply pipe 251, the gas supply pipe 261, and the gas supply pipe 271 through the distributor 125. The nozzle 223, the nozzle 224, and the nozzle 225 are disposed side by side substantially horizontally. A plurality of sets of such nozzles 223, 224, and 225 is disposed vertically. The sets are located corresponding one-to-one to the substrates S. Each nozzle is also referred to as a gas discharger.

The distributor 125 is provided such that gas is supplied from the gas supply pipe 251 to the plurality of nozzles 223, gas is supplied from the gas supply pipe 261 to the plurality of nozzles 224, and gas is supplied from the gas supply pipe 271 to the plurality of nozzles 225. For example, a path through which gas flows is provided per combination of each gas supply pipe and each of the corresponding nozzles. Thus, the respective gases supplied from the gas supply pipes are prevented from mixing together. Therefore, the distributor 125 can inhibit particles from being generated due to gas mixing.

The upstream gas guide 214 includes a supply flow path 227 serving as a gas flow path and a gas guide plate 226 serving as a gas guide. The gas guide plate 226 extends horizontally. The horizontally extending gas guide plate 226 is along the side walls of the supply flow path 227. A plurality of such gas guide plates 226 is disposed vertically. The gas guide plates 226 are fixed to the side walls of the supply flow path 227 without any gap such that gas is prevented from moving to the lower or upper adjacent region beyond a gas guide plate 226. Such prevention of gas from moving beyond enables reliable formation of a gas flow described later.

The gas guide plates 226 each extend horizontally and are each continuous without any hole as a structure. The gas guide plates 226 are each located corresponding to any of the substrates S. A nozzle 223, a nozzle 224, and a nozzle 225 are disposed between each gas guide plate 226 or between a gas guide plate 226 and the supply flow path 227.

The gas discharged from such a nozzle 223, a nozzle 224, or a nozzle 225 is supplied to the surface of the corresponding substrate S. That is, the gas is supplied to the substrate S, laterally to the substrate S. Since the gas guide plates 226 each extend horizontally and are each continuous without any hole as a structure, a mainstream of gas moves horizontally without moving vertically. Therefore, the pressure loss of the gas to reach each substrate S can be vertically uniformed.

With a substrate support 300, described later, supporting substrates S, the downstream gas guide 215 has a top higher than the uppermost substrate S in the substrate support 300 and has a bottom lower than the lowermost substrate S in the substrate support 300. The substrate support 300 is used as a substrate holder that holds substrates S.

The downstream gas guide 215 includes an exhaust flow path 231 serving as a gas flow path and a gas guide plate 232 serving as a gas guide. The gas guide plate 232 extends horizontally. The horizontally extending gas guide plate 232 is along the side walls of the exhaust flow path 231. Furthermore, a plurality of such gas guide plates 232 is disposed vertically. The gas guide plates 232 are fixed to the side walls of the exhaust flow path 231 without any gap such that gas is prevented from moving to the lower or upper adjacent region beyond a gas guide plate 232. Such prevention of gas from moving beyond enables reliable formation of a gas flow described later. A flange 233 is provided on the side of contact with the gas exhaust structure 213 of the exhaust flow path 231.

The gas guide plates 232 each extend horizontally and are each continuous without any hole as a structure. The gas guide plates 232 are each located corresponding to any of the substrates S. Desirably, the gas guide plates 232 are each equivalent in height to the corresponding gas guide plate 226. Furthermore, at the time of processing of the substrates S, desirably, the substrates S are each aligned in height with the corresponding gas guide plates 226 and 232. Due to such a structure, as indicated with arrows in FIG. 1, the gas supplied from each nozzle flows horizontally to pass on the corresponding substrate S and gas guide plate 232. Due to the structure, the gas guide plates 232 can uniform, in pressure loss, the respective gases having passed on the substrates S. Therefore, the gas that passes on each substrate S flows horizontally to the gas exhaust structure 213 without flowing vertically.

Since the gas guide plates 226 and the gas guide plates 232 are provided, pressure loss can be vertically uniformed both on the upstream side of each substrate S and on the downstream side of each substrate S, leading to reliable formation of a horizontal gas flow with no vertical flow from each gas guide plate 226 to the corresponding gas guide plate 232 through the substrate S. Thus, an improvement can be made in the uniformity of film thickness between each substrate S.

The gas exhaust structure 213 is provided on the downstream side of the downstream gas guide 215. The gas exhaust structure 213 includes, mainly, a housing 241 and a gas exhaust pipe connector 242. A flange 243 is provided on the side of location of the downstream gas guide 215 of the housing 241. The flange 233 and the flange 243 are fixed with screws or the like through a cushion, such as an O-ring, because the gas exhaust structure 213 is made of metal and the downstream gas guide 215 is made of quartz. Desirably, the flange 243 is disposed outside the heater 211 such that the heater 211 can be inhibited from influencing such an O-ring.

The gas exhaust structure 213 is in communication with the space of the downstream gas guide 215. The exhaust flow path 231 and the housing 241 are continuous in height as a structure. The top of the exhaust flow path 231 is equivalent in height to the top of the housing 241. The bottom of the exhaust flow path 231 is equivalent in height to the bottom of the housing 241. The housing 241 has an exhaust hole 244 on its downstream side and on its lower or lateral side. The gas exhaust structure 213 serves as a lateral exhaust structure provided laterally to the reaction tube 210 in order to exhaust the gas from the substrates S, laterally.

The gas having passed through the downstream gas guide 215 is exhausted through the exhaust hole 244. In this case, a gas flow containing a vertical flow is formed to the exhaust hole 244 because the gas exhaust structure 213 includes no gas guide plate.

The substrate support 300 including a partition support 310 and a base 311 is stored in the reaction tube 210. The reaction tube 210 has an inner top under which substrates S are disposed. A vacuum conveyance robot performs replacement of substrates S to the substrate support 300 inside a transfer chamber 217 through a substrate inlet, not illustrated. The replaced substrates S in the substrate support 300 are conveyed into the reaction tube 210, followed by processing of forming a thin film on the surface of each substrate S. The substrate inlet is provided, for example, to a side wall of the transfer chamber 217.

The partition support 310 has a plurality of discoid partitions 314 fixed thereto at predetermined pitches. Then, a substrate S is supported between each partition 314, and the substrates S are located at predetermined intervals. The partitions 314 are each disposed above a substrate S, below a substrate S, or between substrates S. The partitions 314 each serve as a spatial blocker between the corresponding substrates S.

In the substrate support 300, a plurality of substrates S is placed at predetermined intervals. The predetermined interval between each of the substrates S placed in the substrate support 300 is identical to the vertical interval between each of the partitions 314 fixed to the partition support 310. The partitions 314 are larger in diameter than the substrates S.

The substrate support 300 supports a plurality of substrates S, for example, five substrates S in a vertical multistage manner. Note that, exemplarily, the substrate support 300 supports five substrates S, but this is not limiting. For example, the substrate support 300 may be capable of supporting 5 to 50 substrates S. Note that the partitions 314 of the partition support 310 are each also referred to as a separator.

An upward/downward drive mechanism 400 drives the substrate support 300 to move upward/downward between the reaction tube 210 and the transfer chamber 217, or drives the substrate support 300 to rotate around the center of the substrates S supported by the substrate support 300.

The reaction tube 210 has a lower portion to which the transfer chamber 217 is disposed through the manifold 216. The vacuum conveyance robot places (mounts) substrates S on the substrate support (hereinafter, also simply referred to as a boat) 300 in the transfer chamber 217 through the substrate inlet or takes out the substrates S from the substrate support 300 in the transfer chamber 217.

The transfer chamber 217 is capable of storing, inside, the upward/downward drive mechanism 400 serving as a first driver that drives the substrate support 300 to move upward/downward or drives the substrate support 300 to rotate. Referring to FIG. 1, the substrate support 300 is stored in the reaction tube 210 due to elevation by the upward/downward drive mechanism 400.

The upward/downward drive mechanism 400 serving as the first driver includes an upward/downward drive motor 410 and a rotation drive motor 430 serving as drive sources and a boat elevator 420 including a linear actuator serving as a substrate-support lift mechanism that drives the substrate support 300 to move upward/downward.

The upward/downward drive motor 410 serving as a partition-support lift mechanism drives a ball screw 411 to rotate to move a nut 412 screwed on the ball screw 411 upward/downward along the ball screw 411. Thus, together with a base plate 402 to which the nut 412 is fixed, the partition support 310 and the substrate support 300 are driven to move upward/downward between the reaction tube 210 and the transfer chamber 217. The base plate 402 is also fixed to a ball guide 415 engaging with a guide shaft 414 and thus is smoothly movable upward/downward along the guide shaft 414. The ball screw 411 has an upper end and a lower end fixed to fixation plates 416 and 413, respectively. The guide shaft 414 has an upper end and a lower end fixed to the fixation plates 416 and 413, respectively.

The rotation drive motor 430 and the boat elevator 420 including the linear actuator serve as a second driver and are fixed to a base flange 401 serving as a lid supported by the base plate 402 through a side plate 403.

The rotation drive motor 430 has a leading end to which a gear 431 is attached and drives a rotation transmission belt 432 engaging with the gear 431, so that a support 440 engaging with the rotation transmission belt 432 is driven to rotate. The support 440 supports the partition support 310 through the base 311. The rotation drive motor 430 drives the support 440 through the rotation transmission belt 432, so that the partition support 310 and the substrate support 300 rotate.

The boat elevator 420 including the linear actuator drives a shaft 421 to move upward/downward. The shaft 421 has a leading end to which a plate 422 is attached. The plate 422 is connected, through a bearing 423, to a support 441 fixed to the substrate support 300. Since the support 441 is connected to the plate 422 through the bearing 423, when the partition support 310 is driven to rotate by the rotation drive motor 430, the substrate support 300 can rotate together with the partition support 310.

Meanwhile, the support 441 is supported by the support 440 through a linear guide bearing 442. Due to such a configuration, in a case where the boat elevator 420 including the linear actuator drives the shaft 421 to move upward/downward, the support 441 fixed to the substrate support 300 can be driven to move upward/downward relative to the support 440 fixed to the partition support 310.

A vacuum bellows 443 is interposed as a connection between the support 440 fixed to the partition support 310 and the support 441 fixed to the substrate support 300.

The base flange 401 serving as a lid has an upper face on which an O-ring 446 for vacuum sealing is disposed. As illustrated in FIG. 1, due to driving of the upward/downward drive motor 410, the base flange 401 is elevated such that its upper face is pressed against the transfer chamber 217, so that the reaction tube 210 has its inside kept airtight.

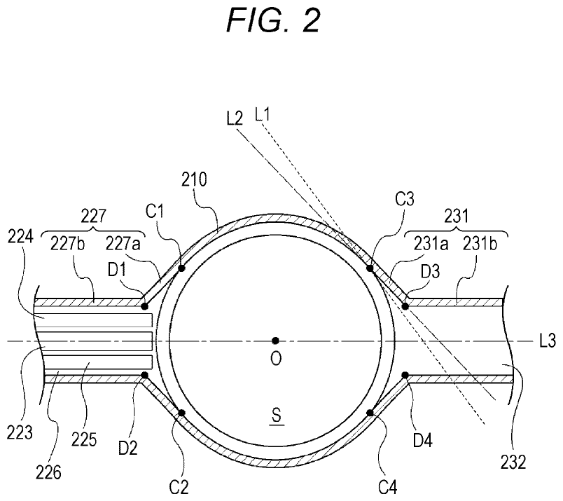

Next, a process vessel will be described in detail with FIG. 2.

Either constituent wall of the supply flow path 227 and either constituent wall of the exhaust flow path 231 are continuous with either constituent wall of the reaction tube 210. Thus, the supply flow path 227, the exhaust flow path 231, and the reaction tube 210 are used as a process vessel in which substrates S are housed and processed. As described above, each constituent wall of the supply flow path 227 and the corresponding constituent wall of the exhaust flow path 231 are continuous, respectively, with the upstream side and downstream side of a gas flow of the corresponding constituent wall of the reaction tube 210. The constituent walls of the reaction tube 210, the constituent walls of the supply flow path 227, and the constituent walls of the exhaust flow path 231 are each made of quartz.

The constituent walls of the supply flow path 227 are used for a gas flow path for supplying gas into the reaction tube 210. The constituent walls of the exhaust flow path 231 are used for a gas flow path for exhausting the gas in the reaction tube 210.

The supply flow path 227 includes a first supply flow path 227a connected to the reaction tube 210 and a second supply flow path 227b that is provided on the upstream side of a gas flow of the first supply flow path 227a and is connected to the reaction tube 210 through the first supply flow path 227a. The first supply flow path 227a is connected continuously to the reaction tube 210 through connections C1 and C2. Thus, the constituent walls of the reaction tube 210 and the constituent walls of the first supply flow path 227a are connected through the connections C1 and C2. The connections C1 and C2 are each located on the boundary between a plane and a curved face and have no protruding structure. The first supply flow path 227a is connected continuously to the second supply flow path 227b through connections D1 and D2. Thus, the constituent walls of the first supply flow path 227a and the constituent walls of the second supply flow path 227b are connected through the connections D1 and D2.

The exhaust flow path 231 includes a first exhaust flow path 231a serving as a first flow path connected to the reaction tube 210 and a second exhaust flow path 231b serving as a second flow path that is provided on the downstream side of a gas flow of the first exhaust flow path 231a and is connected to the reaction tube 210 through the first exhaust flow path 231a. The first exhaust flow path 231a is connected continuously to the reaction tube 210 through connections C3 and C4. Thus, the constituent walls of the reaction tube 210 and the constituent walls of the first exhaust flow path 231a are connected through the connections C3 and C4. The first exhaust flow path 231a is connected continuously to the second exhaust flow path 231b through connections D3 and D4. Thus, the constituent walls of the first exhaust flow path 231a and the constituent walls of the second exhaust flow path 231b are connected through the connections D3 and D4.

As illustrated in FIG. 2, an extension line L1 through the connection C3 of a constituent inner wall of the reaction tube 210 that is the tangent to the reaction tube 210 at the connection C3 and an extension line L2 through the connection C3 of a constituent inner wall of the first exhaust flow path 231a serving as a gas flow path each cross an axis L3 extending from the central axis O of the reaction tube 210 to the exhaust flow path. Due to such a configuration, the connections C3 and C4 are each located on the boundary between a plane and a curved face and have no protruding structure.

At the intersection (connection C3) between the extension line L1 through the connection C3 of a constituent inner wall of the reaction tube 210 and the extension line L2 through the connection C3 of a constituent inner wall of the exhaust flow path 231 serving as a gas flow path, the angle closer to the center of the reaction tube 210 between the extension line L1 and the extension line L2 is an obtuse angle or a straight angle. Due to such a configuration, the connections C3 and C4 are each located on the boundary between a plane and a curved face and have no protruding structure.

Due to the above configuration, even in a case where processing gas hits against the connection C3, its gas flow passes smoothly, leading to inhibition of occurrence of swirling current. Even at the connection C1, C2, or C4, due to a similar configuration, a similar effect can be obtained.

The supply flow path 227 and the exhaust flow path 231 are provided in symmetry across the reaction tube 210. Referring to FIG. 2, the supply flow path 227 and the exhaust flow path 231 are in bilateral symmetry across the reaction tube 210. That is, the supply flow path 227 and the exhaust flow path 231 are provided in point symmetry with respect to the central axis O of the reaction tube 210. The constituent walls of the supply flow path 227, the constituent walls of the reaction tube 210, and the constituent walls of the exhaust flow path 231 are provided in line symmetry with respect to the axis L3. Thus, the gas flow on the supply side and the gas flow on the exhaust side can be identical, resulting in inhibition of occurrence of swirling current. The gas flows on both sides across the axis L3 can be made identical, leading to an improvement in the in-plane thickness uniformity of a film on a substrate.

With substrates S housed in the reaction tube 210, the shortest distance between the inner wall at each of the connections C1 and C2 and the end of every substrate S is shorter than the shortest distance between the corresponding constituent inner wall of the supply flow path 227 and the end of every substrate S. With the substrates S housed in the reaction tube 210, the shortest distance between the inner wall at each of the connections C3 and C4 and the end of every substrate S is shorter than the shortest distance between the corresponding constituent inner wall of the exhaust flow path 231 and the end of every substrate S.

With the substrates S housed in the reaction tube 210, the shortest distance between each constituent inner wall of the reaction tube 210 and the end of every substrate S is shorter than the shortest distance between the constituent inner walls of the supply flow path 227. With the substrates S housed in the reaction tube 210, the shortest distance between each constituent inner wall of the reaction tube 210 and the end of every substrate S is shorter than the shortest distance between the constituent inner walls of the exhaust flow path 231.

The shortest distance between each constituent inner wall of the reaction tube 210 and the end of every substrate S is shorter than the shortest distance between the corresponding constituent inner wall of the supply flow path 227 and the end of every substrate S. The shortest distance between each constituent inner wall of the reaction tube 210 and the end of every substrate S is shorter than the shortest distance between the corresponding constituent inner wall of the exhaust flow path 231 and the end of every substrate S.

The constituent inner walls of the second supply flow path 227b are parallel to the axis L3 and are disposed in line symmetry with respect to the axis L3. That is, the distance between the constituent inner walls of the second supply flow path 227b is constant. The distance between the constituent inner walls of the first supply flow path 227a increases continuously toward the reaction tube 210. That is, the distance from one of the constituent inner walls of the first supply flow path 227a to the axis L3 is longest at the connection C1 on the side of location of the reaction tube 210 and is shortest at the connection D1 on the side of location of the second supply flow path 227b. In addition, the distance from the other constituent inner wall of the first supply flow path 227a to the axis L3 is longest at the connection C2 on the side of location of the reaction tube 210 and is shortest at the connection D2 on the side of location of the second supply flow path 227b. The gas flows on both sides across the axis L3 can be made identical, leading to an improvement in the in-plane thickness uniformity of a film on a substrate.

In other words, the width of the gas flow path is narrower between the connections D1 and D2 than between the connections C1 and C2. That is, the connections C1, C2, D1, and D2 are located such that the gas concentration is lower at the connections C1 and C2 than at the connections D1 and D2.

The constituent inner walls of the second exhaust flow path 231b are parallel to the axis L3 and are disposed in line symmetry with respect to the axis L3. That is, the distance between the constituent inner walls of the second exhaust flow path 231b is constant. The distance between the constituent inner walls of the first exhaust flow path 231a decreases continuously with an increasing distance from the reaction tube 210. Due to such a configuration, the connections C3 and C4 each have no protruding structure. That is, the distance from one of the constituent inner walls of the first exhaust flow path 231a to the axis L3 is longest at the connection C3 on the side of location of the reaction tube 210 and is shortest at the connection D3 on the side of location of the second exhaust flow path 231b. In addition, the distance from the other constituent inner wall of the first exhaust flow path 231a to the axis L3 is longest at the connection C4 on the side of location of the reaction tube 210 and is shortest at the connection D4 on the side of location of the second exhaust flow path 231b. The gas flows on both sides across the axis L3 can be made identical, leading to an improvement in the in-plane thickness uniformity of a film on a substrate.

In other words, the width of the gas flow path is narrower between the connections D3 and D4 than between the connections C3 and C4. The connections D3 and D4 are each located at a predetermined distance from the substrates S. The predetermined distance is determined such that the gas concentration is lower at the connections C3 and C4 than at the connections D3 and D4. Thus, in a region including the connection C3 or C4 close to the substrates S, gas retention and a rise in partial pressure are inhibited with inhibition of occurrence of swirling current, leading to inhibition of a local rise in gas concentration. Note that, since the connections D3 and D4 are each located at the predetermined distance from the substrates S in comparison to the connections C3 and C4, even in a case where swirling current occurs in a region including the connection D3 or D4, the substrates S are less influenced.

Note that the gas concentration at each connection described above corresponds, specifically, to the gas concentration in the space near the corresponding connection. The gas concentration near the corresponding connection corresponds, for example, to the gas concentration in the space in contact with the corresponding connection.

A gas guide plate 226 has no protruding structure and is provided continuously between the constituent inner walls of the first supply flow path 227a and between the constituent inner walls of the second supply flow path 227b. The gas guide plate 226 has a shape along the inner walls of the first supply flow path 227a and the inner walls of the second supply flow path 227b. Thus, the gas guide plate 226 has a width gradually increasing from the second supply flow path 227b to the first supply flow path 227a. The end on the downstream side of a gas flow of the gas guide plate 226, namely, the end on the side of location of the reaction tube 210 of the gas guide plate 226 is arc-like in shape such that the shortest distance between the end on the side of location of the reaction tube 210 of the gas guide plate 226 and the end of the substrate S is equivalent to the shortest distance between each inner wall of the reaction tube 210 and the end of the substrate S. That is, the gas guide plate 226 has a side, which faces the substrate S, in a shape along the outer circumference of the substrate S. The end on the side of location of the reaction tube 210 of the gas guide plate 226 is closer to the center of the reaction tube 210 than the leading ends of nozzles 223 to 225 are.

A gas guide plate 232 has no protruding structure and is provided continuously between the constituent inner walls of the first exhaust flow path 231a and between the constituent inner walls of the second exhaust flow path 231b. The gas guide plate 232 has a shape along the inner walls of the first exhaust flow path 231a and the inner walls of the second exhaust flow path 231b. Thus, the gas guide plate 232 has a width gradually decreasing from the first exhaust flow path 231a to the second exhaust flow path 231b. The end on the upstream side of a gas flow of the gas guide plate 232, namely, the end on the side of location of the reaction tube 210 of the gas guide plate 232 is arc-like in shape such that the shortest distance between the end on the side of location of the reaction tube 210 of the gas guide plate 232 and the end of the substrate S is equivalent to the shortest distance between each inner wall of the reaction tube 210 and the end of the substrate S. That is, the gas guide plate 232 has a side, which faces the substrate S, in a shape along the outer circumference of the substrate S. Thus, swirling current due to a gas guide plate is inhibited from being formed.

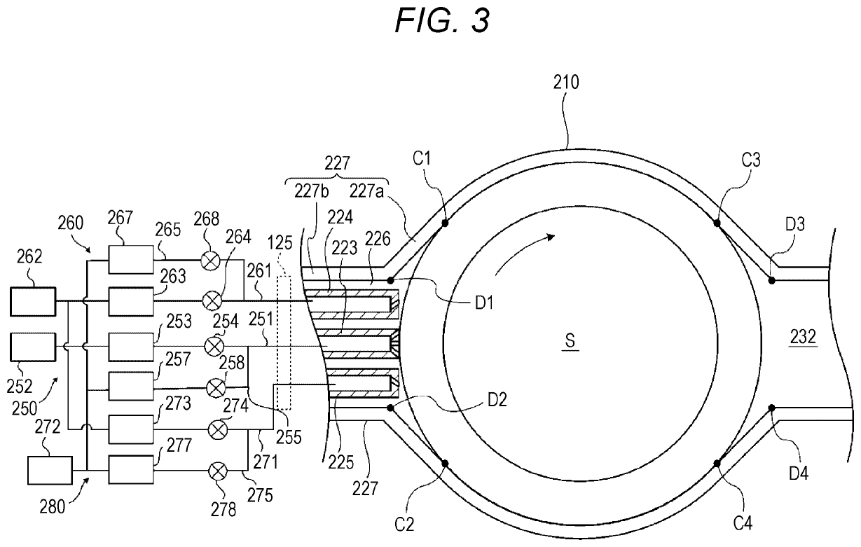

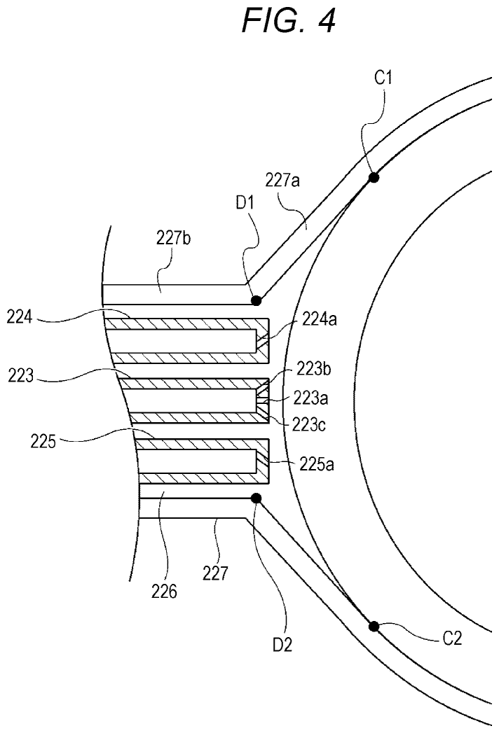

Next, a gas supplier and the periphery thereof will be described in detail with FIGS. 3 and 4.

As illustrated in FIG. 3, a nozzle 223, a nozzle 224, and a nozzle 225 are provided as a gas supplier between gas guide plates 226 or between a gas guide plate 226 and the supply flow path 227 in the supply flow path 227. Such a nozzle 223, a nozzle 224, and a nozzle 225 are provided, on the upstream side in a substantially horizontal direction of a substrate S, in the circumferential direction of the substrate S. The nozzles 223, 224, and 225 are in communication with the reaction tube 210, the supply flow path 227, and the exhaust flow path 231.

The nozzle 223 is disposed at the center in a lateral region to the substrate S, and the nozzles 224 and 225 are disposed on both lateral sides in the horizontal direction of the nozzle 223 at the center in the lateral region to the substrate S. The nozzle 224 is disposed on the downstream side in the rotation direction of the substrate S of the nozzle 223. The nozzle 225 is disposed on the upstream side in the rotation direction of the substrate S of the nozzle 223. That is, the nozzle 223 is disposed between the nozzle 224 and the nozzle 225. In other words, the nozzles 224 and 225 are provided on both sides in the horizontal direction of the nozzle 223. The leading ends of the nozzles 223 to 225 are disposed in the first supply flow path 227a on the downstream side of a gas flow of the connections D1 and D2 and on the upstream side of a gas flow of the connections C1 and C2.

As illustrated in FIG. 4, the leading end of the nozzle 223 has a hole 223a open through a sub-supply path toward the center of the substrate S, a hole 223b that is open through a sub-supply path toward the edge region on the downstream side in the rotation direction of the substrate S and is disposed on the side of location of one of the walls of the reaction tube 210, and a hole 223c that is open through a sub-supply path toward the edge region on the upstream side in the rotation direction of the substrate S and is disposed on the side of location of the other wall of the reaction tube 210. That is, the leading end of the nozzle 223 has the holes 223a, 223b, and 223c open through three sub-supply paths.

The hole 223a is provided in order to supply gas to the center of the substrate S. The hole 223b is provided at a slant on the downstream side in the rotation direction of the substrate S of the hole 223a and is parallel to one of the constituent walls of the first supply flow path 227a, in order to supply gas to the edge region on the downstream side in the rotation direction of the substrate S. That is, the hole 223b is provided in order to supply gas parallel to the first supply flow path 227a on the downstream side in the rotation direction of the substrate S.

The hole 223c is provided at a slant on the upstream side in the rotation direction of the substrate S of the hole 223a and is parallel to the other constituent wall of the first supply flow path 227a, in order to supply gas to the edge region on the upstream side in the rotation direction of the substrate S. That is, the hole 223c is provided in order to supply gas parallel to the first supply flow path 227a on the upstream side in the rotation direction of the substrate S.

Thus, the leading end of the nozzle 223 has the holes 223a, 223b, and 223c in order to supply gas in three directions. Specifically, the extension directions of the hole 223b and the hole 223c are substantially parallel, one-to-one, to the constituent inner walls of the first supply flow path 227a that are the constituent walls of a gas flow path. Thus, swirling current can be inhibited from occurring.

For example, the hole 223a has a diameter of approximately 6 mm that is larger than those of the holes 223b and 223c disposed on both sides of the hole 223a. The holes 223b and 223c facing the edge region of the substrate S have line symmetry with respect to the hole 223a.

The leading end of the nozzle 224 has a hole 224a open to the edge region on the downstream side in the rotation direction of the substrate S. The hole 224a is provided outward at a slant in order to supply gas to the edge region on the downstream side in the rotation direction of the substrate S. That is, the extension direction of the hole 224a is substantially parallel to one of the constituent inner walls of the first supply flow path 227a that is a constituent wall of a gas flow path.

The leading end of the nozzle 225 has a hole 225a open to the edge region on the upstream side in the rotation direction of the substrate S. The hole 225a is provided outward at a slant in order to supply gas to the edge region on the upstream side in the rotation direction of the substrate S. That is, the extension direction of the hole 225a is substantially parallel to the other constituent inner wall of the first supply flow path 227a that is the other constituent wall of the gas flow path.

The holes 224a and 225a facing the edge region of the substrate S have liner symmetry with respect to the hole 223a. The holes 224a and 225a are disposed closer to the edge region than the holes 223b and 223c are. For example, the hole 224a and the hole 225a each have a diameter of approximately 2 mm.

The nozzle 223 is in connection with the gas supply pipe 251. The nozzle 224 is in connection with the gas supply pipe 261. The nozzle 225 is in connection with the gas supply pipe 271.

The gas supply pipe 251 is provided with a source gas source 252, a mass flow controller (MFC) 253 that is a flow rate controller, and a valve 254 that is an on-off valve in the order from upstream.

The source gas source 252 supplies source gas that is processing gas. The source gas corresponds to gas in which at least two atoms of silicon (Si) are bonded and contains Si—Si bonds. For example, used can be hexachlorodisilane (Si₂Cl₆, abbreviation: HCDS) gas that is gas containing Si and chlorine (C1).

A gas supply pipe 255 is connected to the downstream side of the valve 254 of the gas supply pipe 251. The gas supply pipe 255 is provided with an inert gas source 272, a MFC 257, and a valve 258 that is an on-off valve in the order from upstream. The inert gas source 272 supplies inert gas, for example, nitrogen (N₂) gas.

Mainly, the gas supply pipe 251, the MFC 253, the valve 254, the gas supply pipe 255, the MFC 257, the valve 258, and the nozzle 223 serve as a first gas supplier 250.

Mainly, the inert gas supplied from the gas supply pipe 255 acts, at the time of supply of the source gas, as carrier gas that carries the source gas and acts, at the time of purging, as purge gas that purges the gas staying in the reaction tube 210.

As illustrated in FIG. 3, the gas supply pipe 261 is provided with a reactant gas source 262, a MFC 263 that is a flow rate controller, and a valve 264 that is an on-off valve in the order from upstream.

The reactant gas source 262 supplies reactant gas that reacts with the source gas. For example, the reactant gas is gas containing any one of oxygen (O), nitrogen (N), and carbon (C). In the present embodiment, the reactant gas is, for example, nitrogen-containing gas. Examples of such nitrogen-containing gas include hydronitrogen-based gases containing N—H bonds, such as ammonia (NH₃) gas, diazene (N₂H₂) gas, hydrazine (N₂H₄) gas, and N₃H₈ gas.

A gas supply pipe 265 is connected to the downstream side of the valve 264 of the gas supply pipe 261. The gas supply pipe 265 is provided with the inert gas source 272, a MFC 267, and a valve 268 that is an on-off valve in the order from upstream.

Mainly, the gas supply pipe 261, the MFC 263, the valve 264, the gas supply pipe 265, the MFC 267, the valve 268, and the nozzle 224 serve as a second gas supplier 260.

Mainly, the inert gas supplied from the gas supply pipe 265 acts, at the time of supply of the source gas, as carrier gas that carries the source gas and acts, at the time of purging, as purge gas that purges the gas staying in the reaction tube 210.

As illustrated in FIG. 3, the gas supply pipe 271 is provided with the reactant gas source 262, a MFC 273 that is a flow rate controller, and a valve 274 that is an on-off valve in the order from upstream.

A gas supply pipe 275 is connected to the downstream side of the valve 274 of the gas supply pipe 271. The gas supply pipe 275 is provided with the inert gas source 272, a MFC 277, and a valve 278 that is an on-off valve in the order from upstream.

Mainly, the gas supply pipe 271, the MFC 273, the valve 274, the gas supply pipe 275, the MFC 277, the valve 278, and the nozzle 225 serves as a third gas supplier 280.

The inert gas supplied from the gas supply pipe 275 acts, at the time of supply of the source gas, as carrier gas that carries the source gas and acts, at the time of purging, as purge gas that purges the gas staying in the reaction tube 210.

Note that the third gas supplier 280 is identical to the second gas supplier 260 in terms of reactant gas or inert gas to be supplied to the substrate S. Thus, the third gas supplier can be also referred to as another second gas supplier.

Next, an exhauster will be described with FIG. 1. An exhauster 290 that exhausts the atmosphere of the reaction tube 210 includes an exhaust pipe 291 in communication with the reaction tube 210 and is connected to the housing 241 through the gas exhaust pipe connector 242.

As illustrated in FIG. 1, a vacuum pump 294 serving as a vacuum exhaust is connected to the exhaust pipe 291 through a valve 292 serving as an on-off valve and an auto pressure controller (APC) valve 293 serving as a pressure regulator. Thus, vacuum exhaust can be performed such that the pressure in the reaction tube 210 fulfills a predetermined pressure (a predetermined degree of vacuum). The exhaust pipe 291, the valve 292, and the APC valve 293 are collectively referred to as the exhauster 290. The exhauster 290 is also referred to as a process chamber exhauster. Note that the exhauster 290 may include the vacuum pump 294.

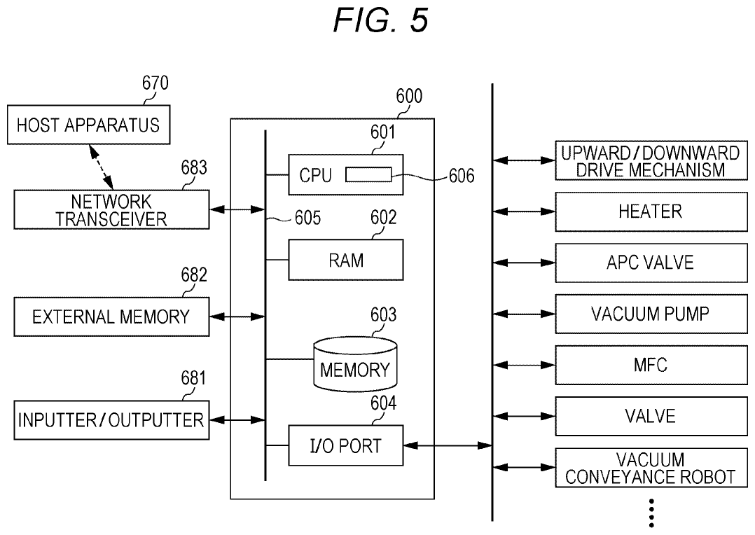

Next, a controller will be described with FIG. 5. The substrate processing apparatus 10 includes a controller 600 that controls the operation of each constituent of the substrate processing apparatus 10.

FIG. 5 schematically illustrates the controller 600. The controller 600 serves as a computer including a central processing unit (CPU) 601, a random access memory (RAM) 602, a memory 603, and an I/O port 604. The RAM 602, the memory 603, and the I/O port 604 are capable of exchanging data with the CPU 601 through an internal bus 605. Transmission/reception of data in the substrate processing apparatus 10 is performed based on an instruction from a transmission/reception instructor 606 that is one function of the CPU 601.

The controller 600 is provided with a network transceiver 683 for connection with a host apparatus 670 through a network. The network transceiver 683 can receive information regarding the processing history of substrates S or the processing schedule for substrates S stored in a pod from the host apparatus 670.

The memory 603 includes, for example, a flash memory and a hard disk drive (HDD). For example, a control program for controlling the operation of the substrate processing apparatus 10 and a process recipe describing procedures and conditions for substrate processing are readably stored in the memory 603.

Note that the process recipe functions as a program for causing the controller 600 to perform each procedure in a substrate processing process, described later, to obtain a predetermined result. Hereinafter, for example, the process recipe and the control program are also collectively and simply referred to as a program. Note that the term “program” in the present specification means the process recipe, the control program, or both thereof. The RAM 602 serves as a memory area (work area) in which the program or data read by the CPU 601 is temporarily stored.

The I/O port 604 is connected to each constituent of the substrate processing apparatus 10.

The CPU 601 reads the control program from the memory 603 and then executes the control program, and additionally reads the process recipe from the memory 603 in response to input of an operation command from an inputter/outputter 681. Then, along the description of the read process recipe, the CPU 601 can control the substrate processing apparatus 10.

The CPU 601 includes the transmission/reception instructor 606. With an external memory (e.g., a magnetic disk such as a hard disk, an optical disc such as a DVD, a magneto-optical disc such as an MO, or a semiconductor memory such as a USB memory) 682 storing the program described above, installation of the program into a computer leads to achievement of the controller 600 according to the present embodiment. Note that, for supply of the program to a computer, the supply through the external memory 682 is not limiting. For example, the program may be supplied through the Internet or a dedicated line, instead of through the external memory 682. Note that the memory 603 and the external memory 682 each serve as a computer-readable recording medium. Hereinafter, the memory 603 and the external memory 682 are also collectively and simply referred to as a recording medium. Note that the term “recoding medium” in the present specification means the memory 603, the external memory 682, or both thereof.

Next, a process of forming a thin film onto a substrate S with the substrate processing apparatus 10 having the configuration described above will be described as a partial process in a semiconductor manufacturing process (substrate processing process). Note that, in the following description, the controller 600 controls the operation of each constituent of the substrate processing apparatus 10.

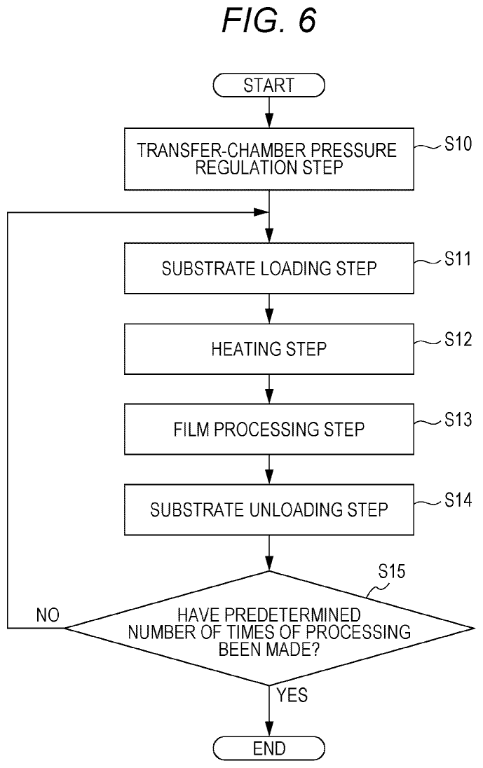

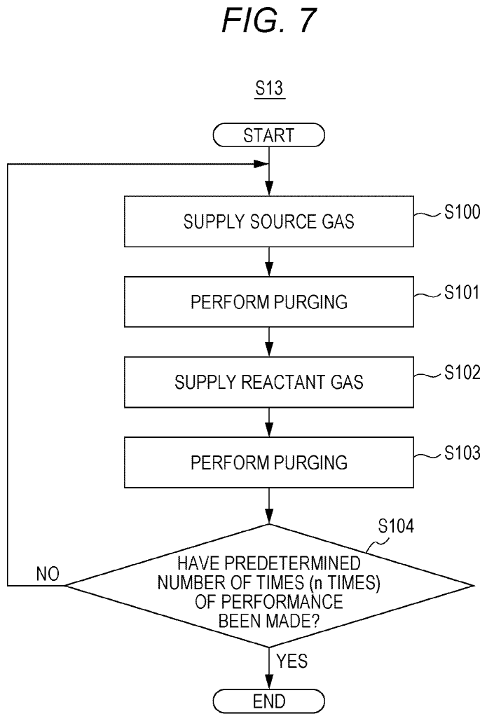

Film-forming processing for forming, by alternate supply of the source gas and the reactant gas, a film onto a substrate S having a surface provided with a groove serving as a recess will be now described with FIGS. 6 and 7.

### (S10)

A transfer-chamber pressure regulation step S10 will be described. In the step, the pressure in the transfer chamber 217 is made identical in level to the pressure in a vacuum conveyance chamber, not illustrated, adjacent to the transfer chamber 217.

### (S11)

Next, a substrate loading step S11 will be described.

When the transfer chamber 217 fulfills the vacuum level, conveyance of substrates S starts. In response to arrival of the substrates S at the vacuum conveyance chamber, a gate valve is made open and then the vacuum conveyance robot loads a substrate S into the transfer chamber 217.

In this case, the substrate S is transferred to the substrate support 300 remaining on standby in the transfer chamber 217. When a predetermined number of substrates S are transferred to the substrate support 300, the vacuum conveyance robot is retracted. In addition, the upward/downward drive mechanism 400 elevates the substrate support 300 to move the substrates S into a process chamber, namely, into the reaction tube 210.

In the movement of the substrates S into the reaction tube 210, the substrates S are positioned such that the surface of each substrate S is aligned with the heights of a gas guide plate 226 and a gas guide plate 232, so that the substrates S are housed in the reaction tube 210.

### (S12)

Next, a heating step S12 will be described.

After the substrates S are loaded in the process chamber, namely, in the reaction tube 210, control is performed such that the pressure in the reaction tube 210 fulfills a predetermined pressure, and additionally control is performed such that the temperature of the surface of every substrate S fulfills a predetermined temperature. The temperature of the heater 211 is controlled such that the substrates S each have, for example, a temperature between 100° C. and 1500° C., inclusive; preferably, a temperature between 200° C. and 1,000° C., inclusive; and more preferably, a temperature between 400° C. and 800° C., inclusive. Preferably, the reaction tube 210 has, for example, an inner pressure of 5 Pa to 100 kPa. That is, the substrates S are processed in a stack on the substrate support 300.

### (S13)

Next, a film processing step S13 will be described. In the film processing step S13, in accordance with the process recipe, the following steps are performed to the substrates S each having a surface provided with a groove serving as a recess, with the process chamber housing the substrates S.

### <Source Gas Supply in Step S100>

First, the source gas is supplied into the reaction tube 210. The valve 254 is opened to cause the source gas to flow into the gas supply pipe 251. The source gas is regulated in flow rate by the MFC 253 and then is supplied into the reaction tube 210 through the distributor 125, the nozzles 223, and the holes 223a, 223b, and 223c. In this case, simultaneously, the valves 268 and 278 are opened to cause the inert gas, such as N₂ gas, to flow into the gas supply pipes 261 and 271. The inert gas is regulated in flow rate by the MFC 267 and then is supplied into the reaction tube 210 through the distributor 125, the nozzles 224, and the holes 224a. In addition, the inert gas is regulated in flow rate by the MFC 277 and then is supplied into the reaction tube 210 through the distributor 125, the nozzles 225, and the holes 225a. Then, the gases are exhausted through the respective spaces on the substrates S, the exhaust flow path 231, the gas exhaust structure 213, and the exhaust pipe 291. That is, in the present step, the source gas and the inert gas are supplied as processing gas into the reaction tube 210.

Such a configuration in which gas is laterally supplied to substrates S and then is laterally exhausted as in the substrate processing apparatus 10 described above enables supply of the source gas in not-yet decomposition, in comparison to a configuration in which gas is supplied to substrates S from below and then is exhausted downward.

### <Purging in Step S101>

In response to elapse of a predetermined time after supply of the source gas starts, the valve 254 is shut to stop the supply of the source gas. In this case, the valves 258, 268, and 278 are opened to supply the inert gas serving as purge gas into the gas supply pipes 255, 265, and 275, respectively. In addition, with the exhaust pipe 291 having the valve 292 and the APC valve 293 kept open, the vacuum pump 294 vacuum-exhausts the reaction tube 210. Thus, the source gas and the reactant gas in a gas phase in the reaction tube 210 can be inhibited from reacting together.

### <Reactant Gas Supply in Step S102>

In response to elapse of a predetermined time after a purge starts, the valves 268 and 278 are shut and the valves 264 and 274 are opened to cause the reactant gas to flow into the gas supply pipes 261 and 271, respectively. The reactant gas is regulated in flow rate by the MFC 263 and then is supplied into the reaction tube 210 through the distributor 125, the nozzles 224, and the holes 224a. In addition, the reactant gas is regulated in flow rate by the MFC 273 and then is supplied into the reaction tube 210 through the distributor 125, the nozzles 225, and the holes 225a. Then, the reactant gas is exhausted through the respective spaces on the substrates S, the downstream gas guide 215, the gas exhaust structure 213, and the exhaust pipe 291. In this case, in order to prevent the reactant gas from entering the gas supply pipe 251, the valve 258 is opened to cause the inert gas to flow through the nozzle 223. That is, in the present step, the reactant gas and the inert gas are supplied as processing gas into the reaction tube 210.

In this case, the reactant gas is supplied to the substrates S, laterally to the substrates S, through the gas supply structure 212. As the reactant gas, used can be N-containing gas, such as NH₃ gas, that is different from the source gas and reacts with the source gas. That is, the reactant gas is supplied to the surfaces of the substrates S, laterally to the substrates S. Then, the reactant gas is supplied into the groove of every substrate S and then reacts with the precursor adhering to the constituent walls of the groove, so that a desired film is formed on each substrate S, in which the groove is filled with the desired film. Specifically, NH₃ gas reacts with HCDS gas on the surface of each substrate S and NH₃ gas supplied in the groove of each substrate S reacts with SiCl₂ adhering to the constituent walls of the groove, leading to formation of a silicon nitride (SiN) film improved in step coverage performance with no void.

### <Purging in Step S103>

In response to elapse of a predetermined time after supply of the reactant gas starts, the valves 264 and 274 are shut to stop the supply of the reactant gas. In this case, the valves 258, 268, and 278 are opened to supply the inert gas serving as purge gas into the gas supply pipes 255, 265, and 275, respectively. In addition, with the exhaust pipe 291 having the valve 292 and the APC valve 293 kept open, the vacuum pump 294 vacuum-exhausts the reaction tube 210. Thus, the source gas and the reactant gas in a gas phase in the reaction tube 210 can be inhibited from reacting together.

### <Predetermined Number of Times of Performance in Step S104>

A cycle in which steps S100 to S103 described above are asynchronously performed in order is performed a predetermined number of times (n times), for example, one or more times to form a film having a predetermined thickness onto each substrate S having a groove. For example, a SiN film is formed.

### (S14)

Next, a substrate unloading step S14 will be described. In the substrate unloading step S14, by following the reverse of the procedure of the substrate loading step S11 described above, the processed substrates S are unloaded outward from the transfer chamber 217.

### (S15)

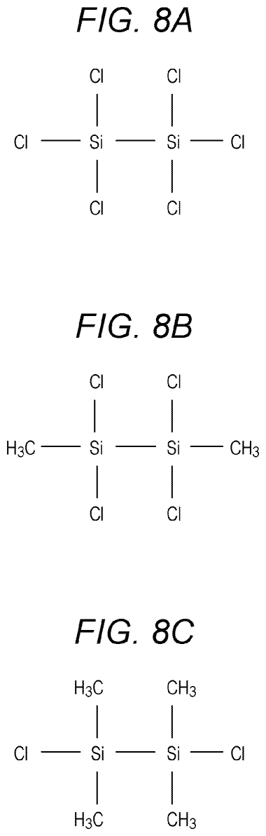

Next, a determination step S15 will be described. In the determination step S15, it is determined whether or not substrate processing has been performed a predetermined number of times. In a case where it is determined that substrate processing has not been performed a predetermined number of times, the processing goes back to the substrate loading step S11 and then the next substrates S are processed. In a case where it is determined that substrate processing has been performed a predetermined number of times, the processing terminates. FIGS. 8A to 8C explanatorily illustrate exemplary gases, in which at least two atoms of silicon (Si) are bonded, for use as the source gas.

As illustrated in FIG. 8A, HCDS gas contains Si and a chloro group (chloride) in its chemical structural formula (per molecule). As illustrated in FIG. 8B, 1,1,2,2-tetrachloro-1,2-dimethyldisilane ((CH₃)₂Si₂Cl₄, abbreviation: TCDMDS) contains a chloro group and an alkylene group in addition to a Si—Si bond. As illustrated in FIG. 8C, 1,2-dichloro-1,1,2,2-tetramethyldisilane ((CH₃)₄Si₂Cl₂, abbreviation: DCTMDS) contains a chloro group and an alkylene group in addition to a Si—Si bond.

The source gas has, under a predetermined condition, as properties, a not-yet decomposition period of time during which a predetermined decomposition rate is kept and a decomposition period of time during which a decomposition rate higher than the predetermined decomposition rate is kept. Note that not-yet decomposition indicates not only a state where gas has not decomposed at all but also a state where gas has decomposed to some extent, namely, a state where gas in not-yet decomposition is dominant. Because of such states, not-yet decomposition is also referred to as low decomposition. Therefore, the not-yet decomposition period of time may be referred to as a low decomposition period of time.

Such a Si—Si bond has a level of energy enabling decomposition due to hitting against a constituent wall of the recess of a substrate S, described later, in the reaction tube 210. Such decomposition means that a Si—Si bond breaks. That is, such a Si—Si bond hits against a wall to break.

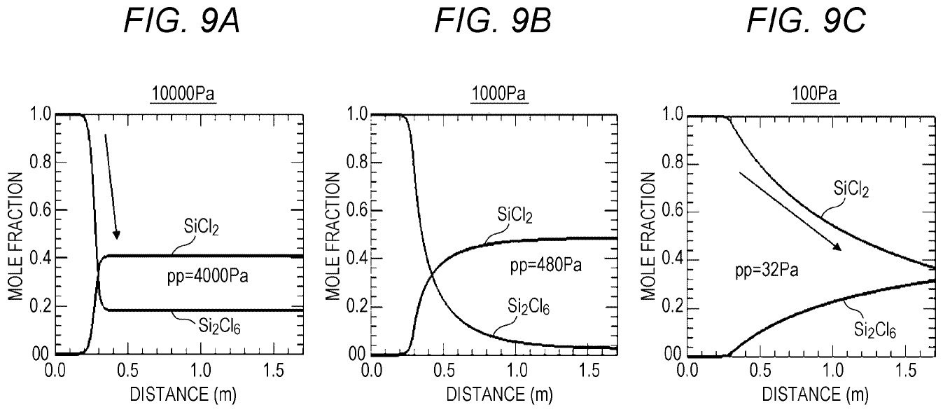

FIGS. 9A to 9C are three graphs of HCDS gas that is an exemplary source gas and is measured at different pressures. The vertical axis and horizontal axis of each graph represent the mole fraction of HCDS and the distance of movement of HCDS, respectively. FIGS. 9A, 9B, and 9C indicate the measurement at 10,000 Pa, the measurement at 1,000 Pa, and the measurement at 100 Pa, respectively. Note that the measurements are identical in temperature. Referring to each graph, a fall in the mole fraction of HCDS (Si₂Cl₆) and a rise in the mole fraction of SiCl₂ are regarded as decomposition of HCDS.

In comparison between the three graphs, a higher pressure causes a rise in the mole fraction of SiCl₂ at a shorter distance. That is, a higher pressure causes more acceleration of decomposition of HCDS.

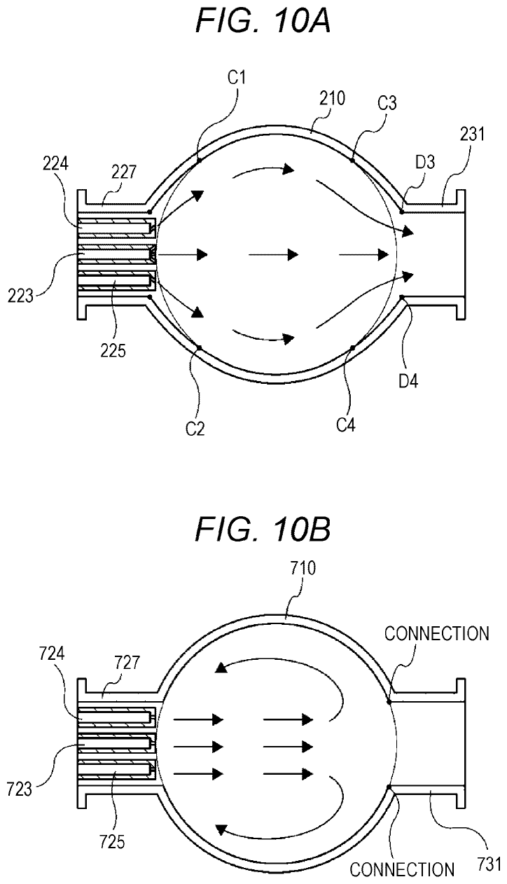

FIG. 10A is a cross sectional view of the process vessel according to the present disclosure. FIG. 10B is a cross sectional view of a process vessel according to a comparative example.

As illustrated in FIG. 10B, the process vessel according to the comparative example includes a reaction tube 710, a supply flow path 727, and an exhaust flow path 731, in which connections, through which the reaction tube 710 and the supply flow path 727 are connected, each have a protruding structure, and connections, through which the reaction tube 710 and the exhaust flow path 731 are connected, each have a protruding structure. Nozzles 723, 724, and 725 each have a leading end provided with a hole in order to supply gas to the center of a substrate S. In the process vessel according to the comparative example, because of a narrow width of opening on the exhaust side (narrow distance between the connections), at the time of exhaust of processing gas from the reaction tube 710, the processing gas hits against the connections near the opening. Thus, swirling current is likely to occur near the connections. Such occurrence of swirling current in the reaction tube 710 may cause the processing gas to stay or a rise in the partial pressure of the processing gas. In a case where gas containing Si—Si bonds, such as HCDS gas, is used as the processing gas, a rise in temperature or a rise in partial pressure causes a higher degree of decomposition. Then, decomposition of the processing gas is accelerated in a region in which a rise is made in temperature or partial pressure, leading to a rise in the concentration of the processing gas in the region. Si—Si bonds break by hitting against the protruding structures. Thus, decomposition of the processing gas is accelerated in the regions, leading to a rise in the concentration of the processing gas in the regions. Thus, the end of a substrate S disposed near each protruding structure and the center of the substrate S are different in the concentration of the processing gas supplied to the surface of the substrate S. Thus, a deterioration may be made in the in-plane thickness uniformity of a film formed on the substrate. In a case where the process vessel is subjected to vacuuming, the protruding structures may be damaged due to intense stress.

In contrast to this, as illustrated in FIG. 10A, the connections (C1 and C2) between the reaction tube 210 and the supply flow path 227 and the connections (C3 and C4) between the reaction tube 210 and the exhaust flow path 231 have no protruding structure. At the time of exhaust of processing gas from the reaction tube 210, the width of an opening on the exhaust side (distance between the connections C3 and C4) is larger than the width of the opening in the process vessel (distance between the connections) illustrated in FIG. 10B. The distance between the center of a substrate S and each of the connections D3 and D4 is longer than the distance between the center of the substrate S and each connection in the process vessel illustrated in FIG. 10B. Thus, since the connections D3 and D4 are each located further away from the substrate S in comparison to the connections of the process vessel illustrated in FIG. 10B, even in a case where swirling current occurs in a region including the connection D3 or D4, the substrate S is less influenced. That is, the processing gas is inhibited from hitting against the walls, leading to inhibition of occurrence of swirling current. Thus, the processing gas is inhibited from staying, leading to inhibition of a local rise in the partial pressure of the processing gas. Thus, even in a case where gas containing Si—Si bonds is used as the processing gas, uniform processing is allowed, leading to an improvement in the in-plane thickness uniformity of a film formed on the substrate. Since the connections (C3 and C4) with the reaction tube 210 have no protruding structure, even in a case where the process vessel is subjected to vacuuming, a gas flow passes smoothly, leading to inhibition of occurrence of swirling current with retention of the vacuum tolerance of the vessel.

Note that formation of a horizontal gas flow has been described above. Preferably, a horizontal main stream of gas is formed as a whole. However, provided that uniform processing to a plurality of substrates is not influenced, a vertically diffused gas flow may be formed.

Needless to say, the terms “identical”, “almost the same”, “equivalent”, and “equal” in the above description are substantially the same in meaning.

### (4) MODIFIED EXAMPLES

Next, modified examples of the process vessel in the embodiment described above will be described in detail. Differences between each of the following modified examples and the embodiment described above will be described in detail.

### Modified Example 1

A modified example of the process vessel described above will be described as compared with the process vessel according to the present disclosure.

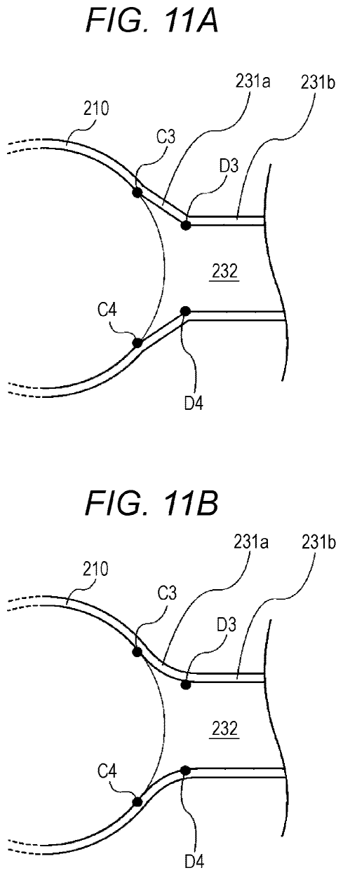

FIG. 11A is a partial cross sectional view of the periphery of the connections C3 and C4 of the process vessel according to the present disclosure. FIG. 11B is a partial cross sectional view of the periphery of connections C3 and C4 of a process vessel according to a modified example.

As illustrated in FIG. 11A, in the embodiment described above, the first exhaust flow path 231a that is linear is connected at a slant to the reaction tube 210 through the connections C3 and C4. The first exhaust flow path 231a that is linear is connected at a slant to the second exhaust flow path 231b through the connections D3 and D4. The gas guide plates 232 are each provided corresponding to the shape between the constituent walls of the first exhaust flow path 231a and the shape between the constituent walls of the second exhaust flow path 231b.

In contrast to this, as illustrated in FIG. 11B, in the modified example, a first exhaust flow path 231a that is curved is connected continuously to a reaction tube 210 through the connections C3 and C4. The first exhaust flow path 231a that is curved is connected continuously to a second exhaust flow path 231b through connections D3 and D4. Gas guide plates 232 are each provided corresponding to the shape between the constituent walls of the first exhaust flow path 231a and the shape between the constituent walls of the second exhaust flow path 231b.

Thus, the process vessel according to the modified example enables a gas flow to pass smoothly, leading to inhibition of occurrence of swirling current, namely, inhibition of gas from staying and inhibition of a rise in the partial pressure of the gas. Thus, an improvement can be made in the in-plane thickness uniformity of a film formed on a substrate. Since the gas guide plates 232 are provided, the respective gases having passed on the substrates S can be uniformed in pressure loss. Therefore, the gas that passes on each substrate S flows horizontally to a gas exhaust structure 213 without flowing vertically. Thus, an improvement can be made in the uniformity of film thickness between each substrate S. Note that a first supply flow path on the upstream side of the reaction tube 210 may be curved and be connected continuously to a second supply flow path on the upstream side of the reaction tube 210, like the first exhaust flow path in the modified example.

### Modified Example 2

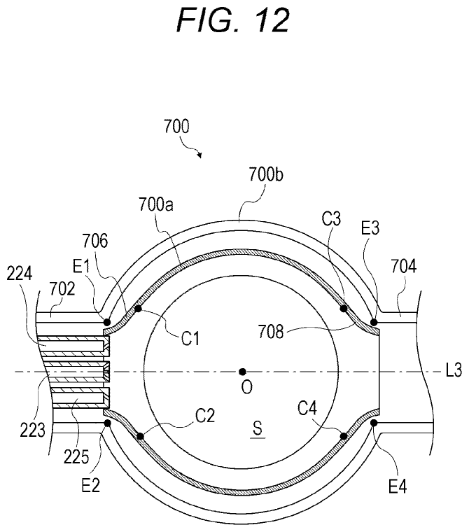

Another modified example of the process vessel described above will be described with FIG. 12.

A process vessel 700 according to the present modified example includes, mainly, an inner tube 700a serving as a first vessel and an outer tube 700b serving as a second vessel. That is, the process vessel 700 has a double structure.

The outer tube 700b is cylindrical in shape. A supply flow path 702 and an exhaust flow path 704 are connected continuously to the upstream side and downstream side of a gas flow of the outer tube 700b, respectively.

A supply flow path 706 and an exhaust flow path 708 are connected continuously to the upstream side and downstream side of a gas flow of the inner tube 700a, respectively.

The outer tube 700b is provided along the outer circumference of the inner tube 700a such that the inner tube 700a and the outer tube 700b are disposed concentrically. The inner tube 700a, the supply flow path 706, the exhaust flow path 708, the outer tube 700b, the supply flow path 702, and the exhaust flow path 704 are each made of a heat-resistant material, such as quartz.

The supply flow path 706 is used as a gas flow path for supplying gas into the inner tube 700a. The exhaust flow path 708 is used as a gas flow path for exhausting the gas in the inner tube 700a.

The supply flow path 706 is connected continuously to the inner tube 700a through connections C1 and C2. The supply flow path 706 is curved such that the distance between the constituent inner walls of the supply flow path 706 increases continuously to the inner tube 700a.

The exhaust flow path 708 is connected continuously to the inner tube 700a through connections C3 and C4. The exhaust flow path 708 is curved such that the distance between the constituent inner walls of the exhaust flow path 708 decreases continuously with an increasing distance from the inner tube 700a.

An opening on the upstream side of a gas flow of the supply flow path 706 is disposed on the upstream side of a gas flow of connections E1 and E2 between the supply flow path 702 and the outer tube 700b. In a case where no nozzles 223 to 225 are disposed, the supply flow path 706 is in communication with the supply flow path 702.

Then, in a case where the nozzles 223 to 225 are disposed in the supply flow path 702 of the outer tube 700b, the leading ends of the nozzles 223 to 225 are disposed at the opening on the upstream side of a gas flow of the supply flow path 706 of the inner tube 700a.

An opening on the downstream side of a gas flow of the exhaust flow path 708 is disposed on the downstream side of a gas flow of connections E3 and E4 between the exhaust flow path 704 and the outer tube 700b.

Thus, the exhaust flow path 708 of the inner tube 700a is in communication with the space between the constituent inner walls of the exhaust flow path 704 of the outer tube 700b. Thus, processing gas supplied into the inner tube 700a is discharged through the exhaust flow paths 708 and 704. Thus, swirling current is inhibited from occurring, that is, gas is inhibited from staying, leading to inhibition of a rise in the partial pressure of the gas. Thus, an improvement can be made in the in-plane thickness uniformity of a film formed on a substrate.

### Other Embodiments

The present embodiment has been specifically described above, but the present disclosure is not limited to the present embodiment. Thus, various modifications can be made without departing form the gist thereof.

Note that, in the embodiment described above, as a configuration, the nozzles 224 and 225 for supplying the inert gas to the edge region of a substrate S are disposed one-to-one on both sides of the nozzle 223 for supplying the source gas. However, the present disclosure is not limited to the configuration, and thus nozzles for supplying the source gas to the edge region of a substrate S may be further disposed one-to-one outside the nozzles 224 and 225. Three or more nozzles may be disposed substantially horizontally in the supply flow path 227.

In the embodiment described above, in the film processing step that the substrate processing apparatus performs, exemplarily, HCDS gas serving as the source gas and NH₃ gas serving as the reactant gas are used to form a film. However, the present disclosure is not limited to the exemplification.

For example, in each embodiment described above, exemplary film-forming processing has been given as processing that the substrate processing apparatus performs, but the present disclosure is not limited to this. That is, the present disclosure can be applied to film forming processing not for the thin film exemplified in each embodiment, in addition to the film-forming processing exemplified in each embodiment. In the present embodiment, the apparatus that processes a plurality of substrates in a stack has been described, but this is not limiting. Thus, the present disclosure can be applied to a single wafer apparatus that performs processing per substrate. Part of the constituents in an embodiment can be replaced with a constituent in another embodiment. A constituent in an embodiment can be added to the constituents in another embodiment. Part of the constituents in each embodiment can be given another constituent, can be deleted, or can be replaced with another constituent.

According to the present disclosure, an improvement can be made in the in-plane thickness uniformity of a film formed on a substrate.

What is claimed is:

1. A substrate processing apparatus comprising:
a vessel for housing a substrate;
a gas flow path continuous with the vessel; and
a first connection through which a constituent wall of the vessel and a constituent wall of the gas flow path are connected, wherein:
an extension line through the first connection of the constituent wall of the vessel and an extension line through the first connection of the constituent wall of the gas flow path each cross an axis extending from a center of the vessel to the gas flow path.

2. The substrate processing apparatus according to claim 1, wherein:
with the substrate housed in the vessel, a distance between the constituent wall of the vessel and the substrate is shorter than a distance between the constituent wall of the gas flow path and another constituent wall of the gas flow path.

3. The substrate processing apparatus according to claim 1, wherein the gas flow path includes a supply flow path configured to supply gas into the vessel; and
the supply flow path is in communication with a gas supplier for supplying gas containing a Si—Si bond.

4. The substrate processing apparatus according to claim 1, wherein an angle closer to the center of the vessel at an intersection between the extension line through the first connection of the constituent wall of the vessel and the extension line through the first connection of the constituent wall of the gas flow path is an obtuse angle or a straight angle.

5. The substrate processing apparatus according to claim 1, wherein the first connection has no protruding structure.

6. The substrate processing apparatus according to claim 1, wherein an angle closer to the center of the vessel at an intersection between the extension line through the first connection of the constituent wall of the vessel and the extension line through the first connection of the constituent wall of the gas flow path is an obtuse angle or a straight angle, or the first connection has no protruding structure.

7. The substrate processing apparatus according to claim 1, wherein the constituent wall of the gas flow path is symmetrical with respect to the axis.

8. The substrate processing apparatus according to claim 1, wherein a distance between the constituent wall of the gas flow path and another constituent wall of the gas flow path decreases continuously with an increasing distance from the vessel.

9. The substrate processing apparatus according to claim 1, wherein the gas flow path includes:
a supply flow path configured to supply gas into the vessel; and
an exhaust flow path configured to exhaust the gas in the vessel; wherein
the supply flow path and the exhaust flow path are provided in symmetry across the vessel.

10. The substrate processing apparatus according to claim 1, wherein the gas flow path includes a supply flow path configured to supply gas into the vessel,
the supply flow path including:
a first supply flow path connected to the vessel through a supply-side first connection serving as the first connection; and
a second supply flow path connected to the first supply flow path through a second connection, the second supply flow path being connected to the vessel through the first supply flow path;
the second connection is located at a predetermined distance from the substrate; and
the predetermined distance is determined such that gas concentration at the supply-side first connection is lower than gas concentration at the second connection.

11. The substrate processing apparatus according to claim 1, wherein the gas flow path includes an exhaust flow path configured to exhaust gas in the vessel,
the exhaust flow path including:
a first exhaust flow path connected to the vessel through an exhaust-side first connection serving as the first connection; and
a second exhaust flow path connected to the first exhaust flow path through a third connection, the second exhaust flow path being connected to the vessel through the first exhaust flow path, and
gas concentration at the exhaust-side first connection is lower than gas concentration at the third connection.

12. The substrate processing apparatus according to claim 1, wherein the gas flow path includes an exhaust flow path configured to exhaust gas in the vessel,
the exhaust flow path including:
a first exhaust flow path connected to the vessel through an exhaust-side first connection serving as the first connection; and
a second exhaust flow path connected to the first exhaust flow path through a third connection, the second exhaust flow path being connected to the vessel through the first exhaust flow path, and
a width of the gas flow path at the third connection is narrower than a width of the gas flow path at the exhaust-side first connection.

13. The substrate processing apparatus according to claim 1, further comprising a gas supplier configured to supply gas into the vessel, wherein:
the gas flow path includes a supply flow path configured to supply the gas into the vessel,
the supply flow path is provided with the gas supplier, and
the gas supplier has a leading end disposed on an upstream side of a gas flow with respect to the first connection.

14. The substrate processing apparatus according to claim 1, further comprising a gas supplier with which the gas flow path is provided, wherein the gas supplier includes:
one or more supply holes; and
a sub-supply path in communication with the one or more supply holes, at least one supply hole of the one or more supply holes is disposed closer to the constituent wall of the vessel; and
a direction of gas supply of the at least one supply hole is parallel to the constituent wall of the gas flow path.

15. The substrate processing apparatus according to claim 1, further comprising a gas guide having a width gradually decreasing with an increasing distance from the vessel, wherein the gas flow path includes an exhaust flow path configured to exhaust gas in the vessel,
the exhaust flow path including:
a first exhaust flow path connected to the vessel through an exhaust-side first connection serving as the first connection; and
a second exhaust flow path connected to the first exhaust flow path through a third connection, the second exhaust flow path being connected to the vessel through the first exhaust flow path; and
the gas guide is provided in the exhaust flow path.

16. The substrate processing apparatus according to claim 1, further comprising:
a second vessel disposed along an outer circumference of a first vessel serving as the vessel; and
another gas flow path provided in the second vessel; wherein the gas flow path is in communication with the other gas flow path.

17. A process vessel comprising:
a vessel capable of housing a substrate;
a gas flow path continuous with the vessel; and
a first connection through which a constituent wall of the vessel and a constituent wall of the gas flow path are connected; wherein an extension line through the first connection of the constituent wall of the vessel and an extension line through the first connection of the constituent wall of the gas flow path each cross an axis extending from a center of the vessel to the gas flow path.

18. A method of processing a substrate comprising supplying gas to the substrate in a substrate processing apparatus, wherein
the substrate processing apparatus includes:
a vessel capable of housing the substrate;
a gas flow path continuous with the vessel; and
a first connection through which a constituent wall of the vessel and a constituent wall of the gas flow path are connected; and
an extension line through the first connection of the constituent wall of the vessel and an extension line through the first connection of the constituent wall of the gas flow path each cross an axis extending from a center of the vessel to the gas flow path.

19. A method of manufacturing a semiconductor device, comprising the method according to claim 18.

20. A non-transitory computer-readable recording medium storing a program that causes, by a computer, a substrate processing apparatus to perform a process comprising the method according to claim 18.
